(19) United States
(12) Patent Application Publication
(10) Pub. No.: US 2014/0139712 A1
(43) Pub. Date: May 22, 2014

(54) IMAGING DEVICE

(71) Applicant: Panasonic Corporation, Osaka (JP)

(72) Inventors: Takahiro Yamamoto, Osaka (JP); Yoshiyuki MATSUNAGA, Kyoto (JP); Makoto YARINO, Kyoto (JP)

(73) Assignee: Panasonic Corporation, Osaka (JP)

(21) Appl. No.: 14/088,514

(22) Filed: Nov. 25, 2013

Related U.S. Application Data
(63) Continuation of application No. PCT/JP2012/003012, filed on May 8, 2012.

(30) Foreign Application Priority Data
May 31, 2011 (JP) 2011-122967

(51) Int. Cl. H04N 5/235; H04N 5/374

(52) U.S. Cl. CPC H04N 5/2353; H04N 5/3742
USPC 348/296

(57) ABSTRACT

An imaging device includes: a stack-type solid-state imaging device which includes pixels including: a photoelectric conversion film which performs photoelectric conversion on light to convert the light into signal charges; a pixel electrode on a first surface of the photoelectric conversion film, the first surface being at a side of the semiconductor substrate; a transparent electrode on a second surface of the photoelectric conversion film, the second surface being opposite to the first surface; and a pixel circuit unit configured to read the signal charges, and accumulate the read signal charges, and the imaging device further includes a control unit configured to control exposure time by selectively applying, to the transparent electrode, a voltage having a first voltage value at which the signal charges move to the pixel circuit unit and a voltage having a second value at which the signal charges move to the pixel circuit unit.

### CROSS REFERENCE TO RELATED APPLICATIONS

This is a continuation application of PCT International Application No. PCT/JP2012/003012 filed on May 8, 2012 designating the United States of America, which is based on and claims priority of Japanese Patent Application No. 2011-122967 filed on May 31, 2011. The entire disclosures of the above-identified applications, including the specifications, drawings and claims are incorporated herein by reference in their entirety.

### FIELD

The present disclosure relates to an imaging device including a stack-type solid-state imaging device.

### BACKGROUND

Conventional Digital Still Cameras (DSCs) with solid-state imaging devices need to have a mechanical shutter for adjusting exposure amounts in capturing still images. Examples of the imaging devices include Charge Coupled Device (CCD) image sensors, Complementary Metal Oxide Semiconductors (CMOS), and Digital Still Cameras (DSC).

However, a DSC with a mechanical shutter is costly. In addition, the mechanical shatter needs to be driven mechanically so that an aperture stop is controlled to adjust an exposure amount, which increases the possibility that the operation part of the mechanical shutter is broken down. Furthermore, it is difficult to reduce the thickness of the lens part with the mechanical part.

However, for use in recent compact DSCs and cameras built in mobile phones, inexpensive camera systems designed to have thin lens parts have been desired.

On the other hand, stack-type solid-state imaging devices have been developed. A stack-type solid-state imaging device is configured to have a photoelectric conversion film via an insulation film above a semiconductor substrate with pixel circuits. Thus, it is possible to form the photoelectric conversion film using a material having a large optical absorption coefficient such as an amorphous silicon, and to therefore increase the aperture ratio in the solid-state imaging device and reduce the thickness of the lens part at the same time. For this reason, such stack-type solid-state imaging devices have been actively developed. One such example is a technique for controlling a voltage to be applied to a photoelectric conversion film of a stack-type solid-state imaging device and thereby controlling a dynamic range (see Patent Literature 1).

### CITATION LIST

### Patent Literature

Japanese Unexamined Patent Application Publication No. 2009-49525

### SUMMARY

### Technical Problem

Stack-type solid-state imaging devices are increasingly expected as described above, but there is no successful technique for manufacturing such a stack-type solid-state imaging device which makes it possible to realize an imaging device such as a camera without requiring any mechanical shutter for exposure control.

In view of this, the present disclosure provides an imaging device including a stack-type solid-state imaging device capable of imaging still images without any mechanical shutter for exposure control.

### Solution to Problem

In order to achieve the above object, an imaging device according to an aspect of the present invention includes a stack-type solid-state imaging device including a plurality of pixels arranged in a matrix above a semiconductor substrate, wherein each of the pixels includes: a photoelectric conversion film which is formed above the semiconductor substrate and performs photoelectric conversion on light to convert the light into signal charges; a pixel electrode formed on a first surface of the photoelectric conversion film, the first surface being at a side of the semiconductor substrate; a transparent electrode formed on a second surface of the photoelectric conversion film, the second surface being opposite to the first surface; and a pixel circuit unit configured to read the signal charges generated through the photoelectric conversion by the photoelectric conversion film via the pixel electrode, and accumulate the read signal charges, the imaging device further including a control unit configured to control exposure time by selectively applying, to the transparent electrode, a voltage having a first voltage value at which the signal charges generated through the photoelectric conversion by the photoelectric conversion film move to the pixel circuit unit and a voltage having a second voltage value at which the signal charges do not move to the pixel circuit unit.

With this structure, the imaging device according to an aspect of the present disclosure can control the exposure time without any mechanical shutter for exposure control. Thus, the imaging device can capture still images without any mechanical shutter.

In addition, the control unit may be configured to perform: exposure start control for starting exposure by switching from the voltage having the second voltage value to the voltage having the first voltage value to be applied to the transparent electrode; and exposure end control for ending the exposure by switching from the voltage having the first voltage value to the voltage having the second voltage value to be applied to the transparent electrode, after the exposure start control, and the pixel circuit unit may be configured to read the signal charges generated through the photoelectric conversion by the photoelectric conversion film during an exposure period starting when the exposure start control is performed and ending when the exposure end control is performed, and may accumulate the read signal charges.

In addition, the control unit may be further configured to perform read control for sequentially reading signal charges accumulated in a plurality of the pixel circuit units included in the respective pixels, after the exposure end control.

In addition, the pixel circuit unit may be connected to the pixel electrode, and may include: a first electric charge accumulation unit configured to accumulate the signal charges; a second electric charge accumulation unit; and a transfer transistor formed between the first electric charge accumulation unit and the second electric charge accumulation unit, and in the read control, the control unit may be configured to: apply the voltage having the second voltage value to the transparent electrode and switch ON the transfer transistor to transfer the signal charges accumulated in the first electric charge accumulation unit to the second electric charge accumulation unit; and sequentially read, from the pixels, signals according to signal charges accumulated in a plurality of the second electric charge accumulation units.

With this structure, the imaging device according to an aspect of the present disclosure can cause the signal charges to move from the first electric charge accumulation units of the pixels to the second electric charge accumulation units simultaneously, and then sequentially read the signal charges in the second electric charge accumulation units of the respective pixels. In this way, the time differences between the read operations for the pixels are reduced, which reduces distortion in the resulting images.

In addition, the control unit may be further configured to perform reset control for (i) applying the voltage having the second voltage value to the transparent electrode, before the exposure start control, and (ii) resetting signal charges accumulated in a plurality of the pixel circuit units, before the exposure start control.

In addition, the control unit may be further configured to perform the reset control, after the read control.

In addition, the pixel circuit unit may include a reset transistor for resetting the signal charges accumulated in the pixel circuit unit, and in the reset control, the control unit may be configured to reset the signal charges accumulated in the pixel circuit unit by switching ON the reset transistor using a tapered signal.

With this structure, the imaging device according to an aspect of the present disclosure can reduce random noise which occurs at the time of reset.

The present disclosure can be realized not only as an imaging device, but also as an imaging device control method having the steps corresponding to the unique units of the imaging device.

Furthermore, the present disclosure can be realized as a semiconductor integrated circuit (LSI) including some or all of the functions of the imaging device.

### Advantageous Effects

As described above, the present disclosure makes it possible to provide an imaging device including a stack-type solid-state imaging device capable of imaging still images without any mechanical shutter for exposure control.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a block diagram of a solid-state imaging device according to an embodiment of the present disclosure.

FIG. 2 is a cross-sectional view of a solid-state imaging device according to the embodiment of the present disclosure.

FIG. 3 is a block diagram of an imaging device according to a comparison example in the present disclosure.

FIG. 4 is a block diagram of an imaging device according to the embodiment of the present disclosure.

FIG. 5 is a flowchart for capturing a still image by the imaging device according to the embodiment of the present disclosure.

FIG. 6 is a time chart for capturing a still image by the imaging device according to the embodiment of the present disclosure.

FIG. 7 shows operations in monitor mode performed by the solid-state imaging device according to the embodiment of the present disclosure.

FIG. 8 shows operations at the time of reset by the solid-state imaging device according to the embodiment of the present disclosure.

FIG. 9 shows operations at the time of starting exposure by the solid-state imaging device according to the embodiment of the present disclosure.

FIG. 10 shows operations at the time of ending the exposure by the solid-state imaging device according to the embodiment of the present disclosure.

FIG. 11 shows operations at the time of reading by the solid-state imaging device according to the embodiment of the present disclosure.

### DESCRIPTION OF EMBODIMENT

Hereinafter, an exemplary embodiment of an imaging device is disclosed in detail below with reference to the drawings. The embodiment described below shows a specific example. The numerical values, shapes, materials, structural elements, the arrangement and connection of the structural elements, steps, the processing order of the steps etc. shown in the following exemplary embodiment are mere examples, and therefore do not limit the scope of the appended Claims and their equivalents. Therefore, among the structural elements in the following exemplary embodiment, structural elements not recited in any one of the independent claims defining the most generic concept of the present disclosure are described as arbitrary structural elements of the exemplary embodiment.

An imaging device according to an embodiment of the present disclosure controls exposure time by selectively applying, to a photoelectric conversion unit, (i) a voltage having a first voltage value at which signal charges photo-electrically converted by a photoelectric conversion film move to a pixel circuit unit and (ii) a voltage having a second voltage value at which signal charges do not move to the pixel circuit unit.

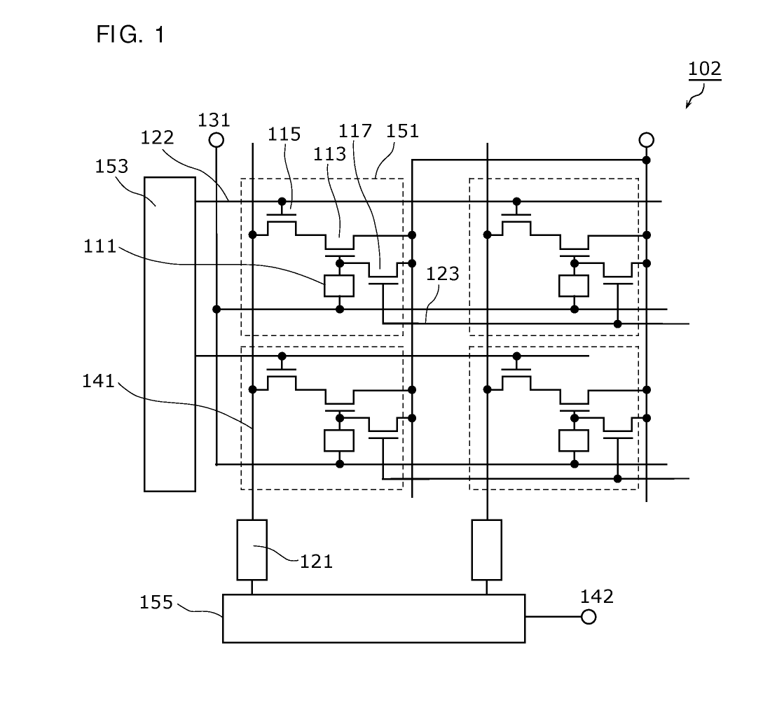

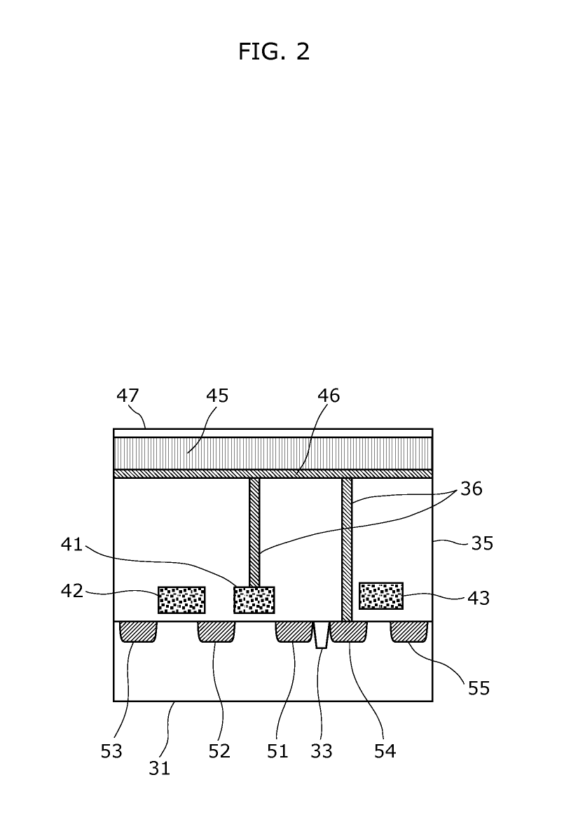

In this way, the imaging device can capture still images without any mechanical shutter for exposure control. With reference to FIG. 1 and FIG. 2, a description is given of a structure of the solid-state imaging device for use in the imaging device according to this embodiment.

FIG. 1 is a diagram of a circuit structure of the solid-state imaging device 102 according to this embodiment. The solid-state imaging device 102 shown in FIG. 1 is a stack-type solid-state imaging device. The solid-state imaging device 102 includes: a plurality of pixels (unit cells) 151 arranged in a matrix; a vertical scanning unit 153 which supplies various kinds of timing signals to the pixels 151; and a horizontal signal reading unit 155 which sequentially reads the signals of the pixels 151 to the horizontal output terminal 142. In FIG. 1, the pixels 151 are arranged in two rows and two columns, but the number of rows and the number of columns may be arbitrarily set.

Each of the pixels 151 includes: a photoelectric conversion unit 111; an amplifier transistor 113 having a gate connected to the photoelectric conversion unit 111; a reset transistor 117 having a drain connected to the photoelectric conversion unit 111; and a selection transistor 115 connected in series with the amplifier transistor 113.

The photoelectric conversion unit 111 is connected between (i) the gate of the amplifier transistor 113 and the drain of the reset transistor 117 and (ii) the photoelectric conversion unit control line 131. The gate of the selection transistor 115 is connected to the vertical scanning unit 153 via an address control line 122. The gate of the reset transistor 117 is connected to the vertical scanning unit 153 via a reset control line 123.

The address control line 122 and the reset control line 123 are provided for a corresponding one of the rows. The photoelectric conversion unit control line 131 is common to all the pixels. The vertical signal line 141 is provided for a corresponding one of the columns and is connected to the horizontal signal reading unit 155 via a column signal processor 121. The column signal processor 121 performs signal noise canceling represented by correlated double sampling, and analog to digital conversion.

FIG. 2 shows a cross-sectional view of one of the pixels 151 shown in FIG. 1 and included in the solid-stage imaging device according to this embodiment.

As shown in FIG. 2, the amplifier transistor 113, the selection transistor 115, and the reset transistor 117 are formed above a semiconductor substrate 31 made of silicon. The amplifier transistor 113 includes a gate electrode 41, a dispersion layer 51 which is a drain, and a dispersion layer 52 which is a source. The selection transistor 115 includes a gate electrode 42, a dispersion layer 52 which is a drain, and a dispersion layer 53 which is a source. The source of the amplifier transistor 113 and the drain of the selection transistor 115 are formed with the common dispersion layer 52. The reset transistor 117 includes a gate electrode 43, a dispersion layer 54 which is a drain, and a dispersion layer 55 which is a source. The dispersion layer 51 and the dispersion layer 54 are separated by an element isolation area 33.

On the semiconductor substrate 31, an insulation layer 35 is formed to cover the respective transistors. On the insulation film 35, the photoelectric conversion unit 111 is formed.

The photoelectric conversion unit 111 includes: a photoelectric conversion film 45 made of amorphous silicon etc.; a pixel electrode 46 formed below the photoelectric conversion film 45 (in contact with the lower surface at the side of the semiconductor substrate 31); and a transparent electrode 47 formed on the photoelectric conversion film 45 (in contact with the upper surface opposite to the lower surface at the side of the semiconductor substrate 31). The photoelectric conversion film 45 converts light into signal charges. The pixel electrode 46 is connected, via a contact 36, to the gate electrode 41 of the amplifier transistor 113 and the dispersion layer 54 which is the source of the reset transistor 117. The dispersion layer 54 connected to the pixel electrode 46 functions as an accumulation diode.

With the structure, light from a subject is incident onto the solid-state imaging device 102 according to this embodiment and is absorbed by the photoelectric conversion film 45, resulting in hole and electron pairs according to the amount of the absorbed light. When a positive voltage is applied to the transparent electrode 47, the electrons in the converted electron and hole pairs are moved toward the transparent electrode 47 to reach a power source (not shown) connected to the transparent electrode 47. The holes are moved toward the dispersion layer 54 and accumulated in the dispersion layer 54.

Hereinafter, a description is given of the imaging device including the aforementioned solid-stage imaging device 102, according to this embodiment.

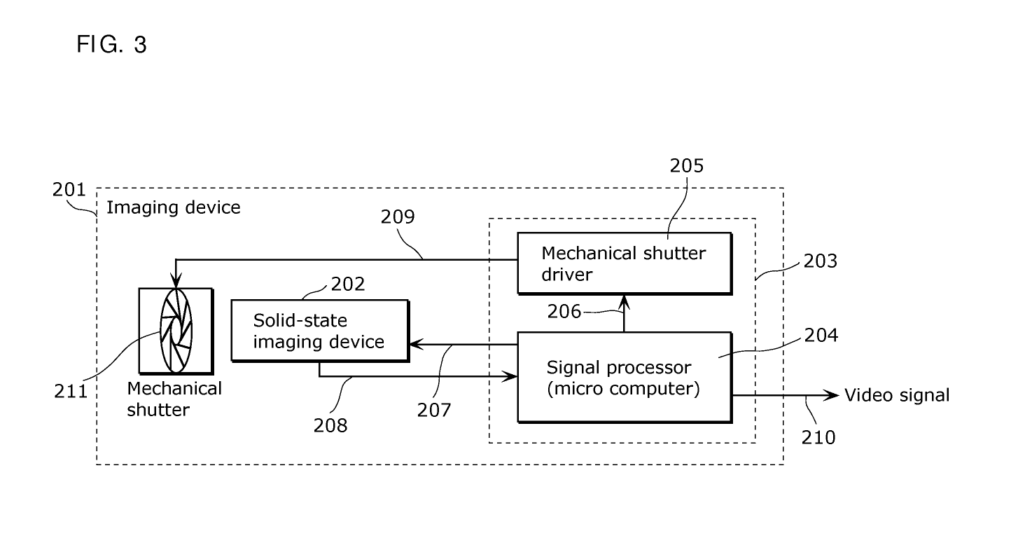

As a comparison example, FIG. 3 shows a structure of an imaging device including a mechanical shutter. The imaging device 201 shown in FIG. 3 includes a solid-state imaging device 202, a control unit 203, and a mechanical shutter 211. The control unit 203 includes a signal processor 204 which processes video signals and a mechanical shutter driver 205 which drives the mechanical shutter 211.

The solid-state imaging device 202 is, for example, a CCD image sensor or a CMOS image sensor.

Next, imaging operations by the imaging device 201 are described. The signal processor 204 computes or sets an exposure amount in advance, and outputs a control signal 206 for controlling the mechanical shutter 211 to the mechanical shutter driver 205. In addition, the signal processor 204 outputs, to the solid-state imaging device 202, a control signal 207 for controlling driving of the solid-stage imaging device 202 and an exposure amount by an electron shutter.

The mechanical shutter driver 205 outputs a control signal 209 for adjusting an exposure amount to the mechanical shutter 211 according to the control signal 206 from the signal processor 204. The mechanical shutter 211 adjusts an aperture stop according to the control signal 209, and closes and opens the mechanical shutter according to the appropriate exposure amount when capturing a still image.

Here, the mechanical shutter 211 increases the cost and the possibility that a breakdown occurs because a mechanical driving is required to adjust the aperture stop. In addition, the mechanical shutter 211 makes it difficult to reduce the thickness of the lens part. Light whose amount is adjusted for exposure by the mechanical shutter 211 is converted into electric signals (output signals 208) by the solid-state imaging device 202. Next, the signal processor 204 processes the output signals 208 from the solid-state imaging device 202, and outputs resulting video signals 210.

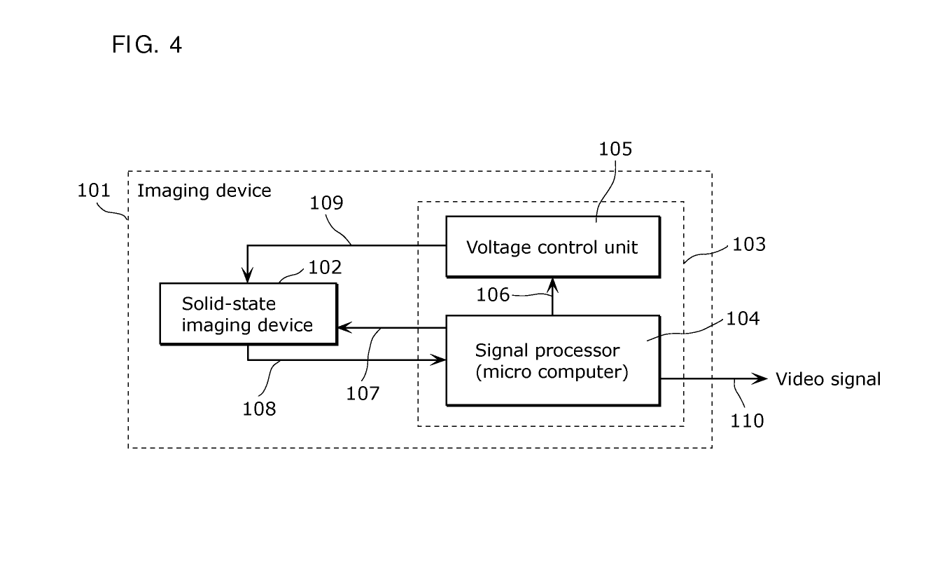

Next, a description is given of an imaging device according to this embodiment of the present disclosure. FIG. 4 is a structure of the imaging device 101 according to this embodiment.

The imaging device 101 according to this embodiment shown in FIG. 4 includes a stack-type solid-state imaging device 102 and a control unit 103. The control unit 103 includes: a signal processor 104; and a voltage control unit 105 which controls a voltage to be applied to a photoelectric stack film included in the stack-type solid-state imaging device 102.

Next, imaging operations by the imaging device 101 according to this embodiment are described. The signal processor 104 computes or sets an exposure amount in advance, and outputs a control signal 106 for controlling an exposure amount to the voltage control unit 105. In addition, the signal processor 104 outputs, to the stack-type solid-state imaging device 102, a control signal 107 for controlling driving of the solid-stage imaging device 102 and an exposure amount by the electron shutter.

The voltage control unit 105 outputs a voltage 109 to be applied to the photoelectric stack film, to the stack-type solid-state imaging device 102, according to the control signal 106 from the signal processor 104. In this way, the voltage control unit 105 controls whether or not to move carriers generated through the photoelectric conversion, with the photoelectric stack film of the stack-type solid-state imaging device 102.

More specifically, the voltage control unit 105 generates, as voltages 109, (i) a voltage having a first voltage value V1 at which carriers generated through the photoelectric conversion can move and (ii) a voltage having a second voltage value V2 at which carriers generated through the photoelectric conversion cannot move. The voltages 109 are selectively applied to the transparent electrode 47 of the photoelectric conversion unit 111 via the photoelectric conversion unit control line 131. In this way, the voltage control unit 105 controls whether or not to move carriers generated through the photoelectric conversion.

In other words, the voltage control unit 105 controls exposure time by selectively applying the voltage having the first voltage value

V1 and the voltage having the second voltage value V2 to the transparent electrode 47. More specifically, the exposure time is the time from when a switch is made to the voltage 109 having the first voltage value V1 at which the carriers generated through the photoelectric conversion can move to when a switch is made back to the voltage 109 having the second voltage value V2 at which the carriers generated through the photoelectric conversion cannot move. In other words, the imaging device 101 can adjust an exposure amount without any mechanical shutter, and therefore can capture a still image without any mechanical shutter.

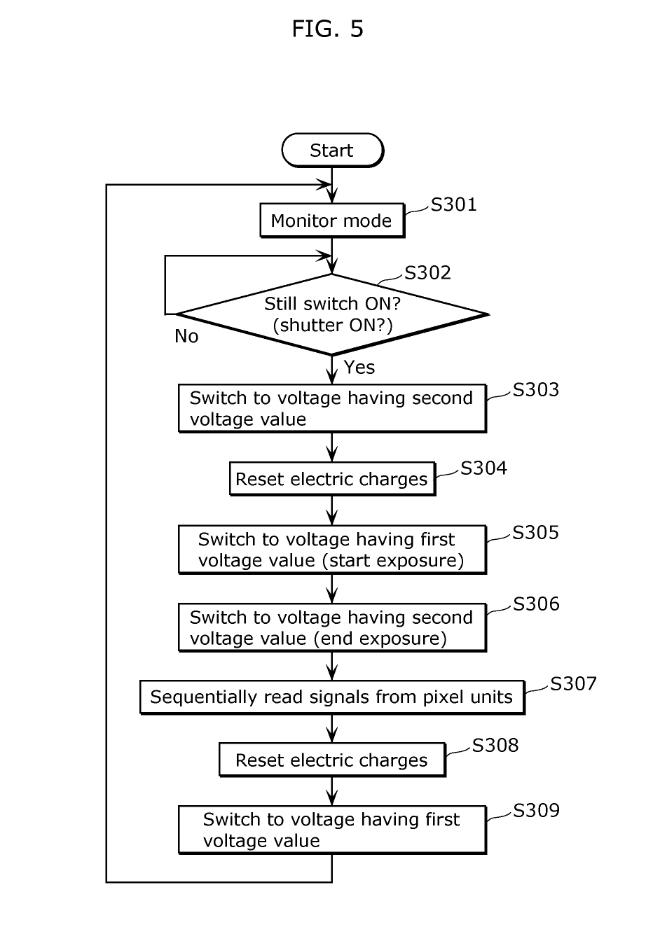

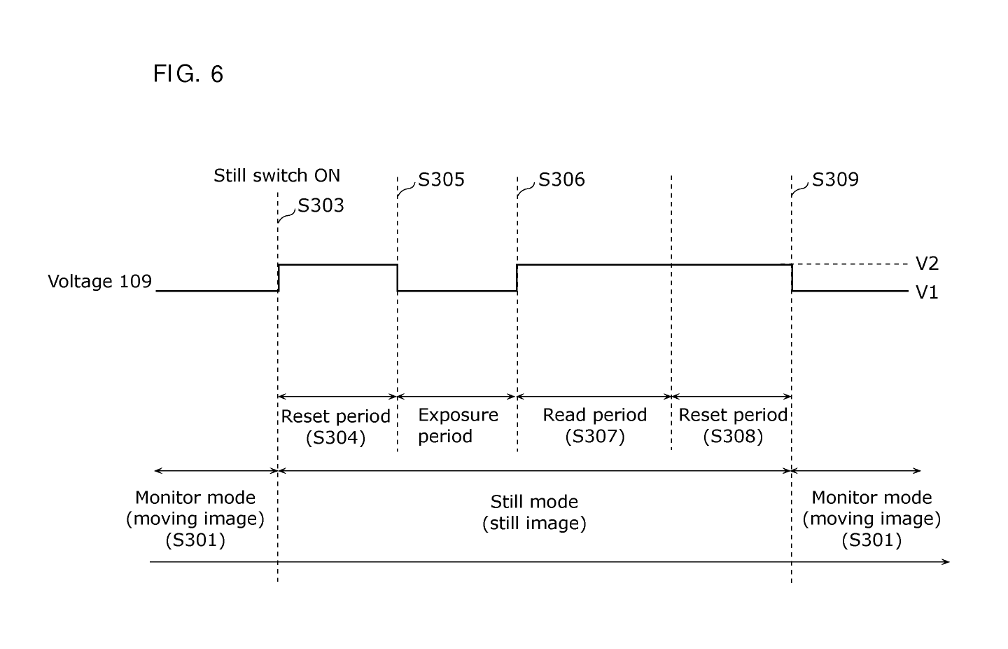

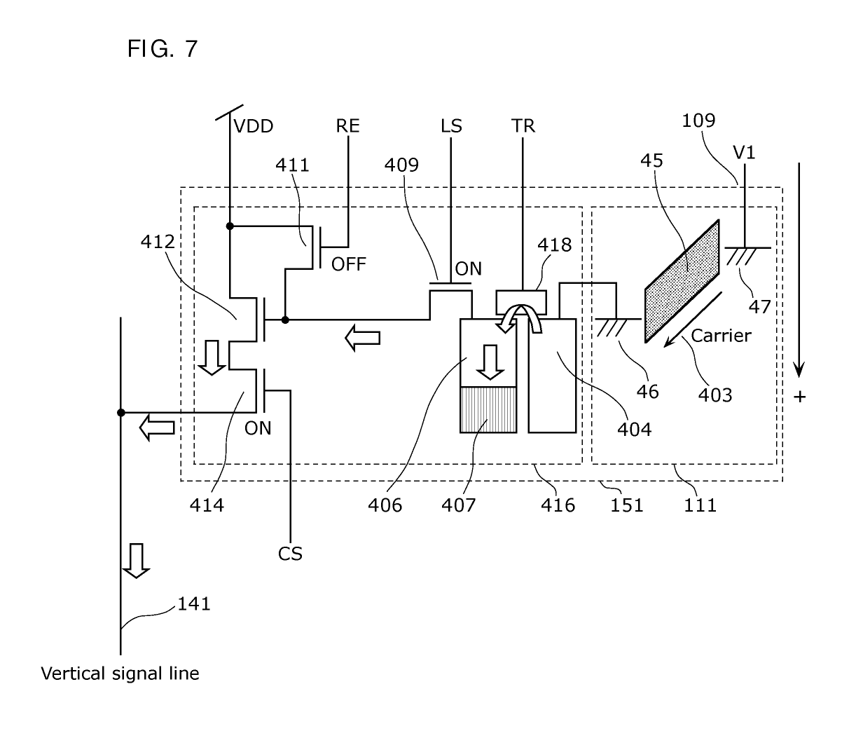

FIG. 5 is a flowchart of processes for imaging a still image performed by the imaging device 101. FIG. 6 is a time chart of processes for imaging a still image performed by the imaging device 101. Each of FIG. 7 to FIG. 11 is a diagram showing potentials in and operations by the solid-state imaging device 102. For convenience of explanation, only one pixel 151 is shown in each of FIG. 7 to FIG. 11, but the stack-type solid-stage imaging device 102 includes a plurality of pixels 151 arranged in a matrix.

As shown in each of FIG. 5 and FIG. 6, the imaging device 101 normally operates in monitor mode (S301). In addition, the signal processor 204 calculates an appropriate exposure amount in advance, or a user manually sets an exposure amount. When capturing an image, the user presses a still switch (a shutter) (Yes in S302).

[Monitor Mode (Moving Image)]

FIG. 7 is a diagram showing potentials in monitor mode (S301) shown in FIG. 5.

Here, a structure of a pixel 151 is explained.

As shown in FIG. 7, the pixel 151 includes a photoelectric conversion unit 111 and a pixel circuit unit 416 formed above the semiconductor substrate 31.

The pixel circuit unit 416 reads the signal charges photo-electrically converted by the photoelectric conversion film 45 via the pixel electrode 46, and accumulates the read signal charges. In addition, the pixel circuit unit 416 outputs the signal according to the accumulated signal charges to the vertical signal line 141.

The pixel circuit unit 416 includes: an amplifier transistor 412, a reset transistor 411, a first electric charge accumulation unit 404, a second electric charge accumulation unit 406, a line selection transistor 409, a column selection transistor 414, and a transfer transistor 418.

The first electric charge accumulation unit 404 is connected to the pixel electrode 46, and accumulates signal charges (carriers 403) generated by the photoelectric conversion film 45. This first electric charge accumulation unit 404 also serves as either a source or a drain of the transfer transistor 418.

The transfer transistor 418 connects or disconnects the first electric charge accumulation unit 404 and the second electric charge accumulation unit 406. The gate of the transfer transistor 418 is supplied with a read signal TR.

The second electric charge accumulation unit 406 also serves as either a source or a drain of the transfer transistor 418, and accumulates, as electric charges 407, carriers 403 transferred from the first electric charge accumulation unit 404 via the transfer transistor 418.

The line selection transistor 409 is connected between the second electric charge accumulation unit 406 and the gate of the amplifier transistor 412. The gate of the line selection transistor 409 is supplied with a line selection signal LS.

The amplifier transistor 412 amplifies electric charges 407 accumulated in the second electric charge accumulation unit 406, and outputs the amplified signals to the vertical signal line 141 via the column selection transistor 414.

The reset transistor 411 resets the electric charges 407 accumulated in the pixel circuit unit 416. The gate of the reset transistor is supplied with a reset signal RE.

The column selection transistor 414 is connected in series with the amplifier transistor 412. The gate of the column selection transistor 414 is supplied with a column selection signal CS.

Each of FIG. 7 to FIG. 11 shows a pixel structure which enables global shutter operations. Although the pixel 151 includes five transistors therein, but this circuit structure is a non-limiting example. For example, as shown in FIG. 1, the pixel 151 may be configured to have three transistors. More specifically, the pixel 151 does not have one or both of the transfer transistor 418 and the line selection transistor 409.

Hereinafter, operations in monitor mode (S301) are explained.

As shown in FIG. 7, in monitor mode (S301), a voltage 109 having a first voltage value V1 at which carriers 403 generated through photoelectric conversion can move is supplied from the voltage control unit 105 to the transparent electrode 47. In other words, the voltage having the first voltage value V1 allows the signal charges (carriers 403) photo-electrically converted by the photoelectric conversion film 45 to move to the pixel circuit unit 416 via the pixel electrode 46. On the other hand, the voltage having the second voltage value V2 does not allow the signal charges (carriers 403) photo-electrically converted by the photoelectric conversion film 45 to move to the pixel circuit unit 416 via the pixel electrode 46. In other words, the voltage having the second voltage value V2 discharges the signal charges (carriers 403) photo-electrically converted by the photoelectric conversion film 45 via the transparent electrode 47.

Thus, the carriers 403 generated through the photoelectric conversion are accumulated as electric charges 407 in the first electric charge accumulation unit 404 of the pixel circuit unit 416. In other words, a read signal TR which becomes effective switches ON the transfer transistor 418. This triggers movement of electric charges 407 from the first electric charge accumulation unit 404 to the second electric charge accumulation unit 406.

In addition, since read scanning is performed on a per row basis, time differences are made between timings for exposing the rows, producing distortion in a resulting image. On the other hand, in this embodiment, electric charges 407 are moved from the first electric charge accumulation unit 404 to the second electric charge accumulation unit 406, and then the electric charges 407 in the second electric charge accumulation unit 406 are sequentially read out. This prevents generation of pixel reading time differences, and thereby prevents generation of distortion in a resulting image.

Next, a line selection signal LS and a column selection signal CS become effective, the amplifier transistor 412 amplifies electric charges 407. The amplified signals are output as output signals 108 of the stack-type solid-stage imaging device 102 via the vertical signal line 141. This output signals 108 are processed by the signal processor 204, and the processed signals are output as video signals 110 from the imaging device 101.

[All Reset]

When a still switch is pressed (Yes in S302), the signal processor 104 applies a voltage having a second voltage value V2 to the transparent electrode 47, and performs reset control for resetting signal charges accumulated in the pixel circuit unit 416.

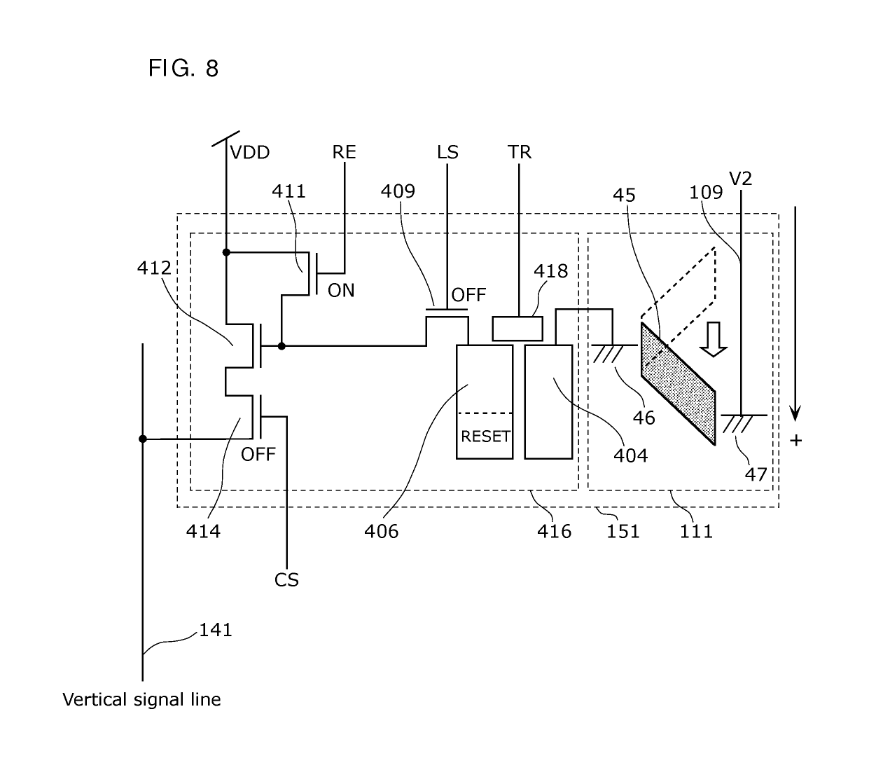

More specifically, the signal processor 104 outputs a control signal 106 to the voltage control unit 105 so that a voltage 109 to be applied to the transparent electrode 47 has the second voltage value V2 at which carriers generated through the photoelectric conversion cannot move. In response to this, as shown in FIG. 8, the voltage control unit 105 switches to a voltage 109 having the second voltage value V2 at which the carriers generated through the photoelectric conversion cannot move, as a voltage to be applied to the transparent electrode 47 (S303).

This switching disables the carriers generated through the photoelectric conversion to move in the photoelectric conversion film 45. In this state, the signal processor 104 activates reset signals RE and line selection signals LS for all the pixels 151. Thus, the reset transistors 411 and the line selection transistors 409 are switched ON. In this way, electric charges accumulated in the second electric charge accumulation units 406 of all the pixels 151 are reset. More specifically, the voltages of the second electric charge accumulation units 406 are reset to a reset level (VDD) (S304).

Here, when light enters on a PN junction part in the circuit, carriers are generated through photoelectric conversion, and unnecessary electric charges are accumulated in the second electric charge accumulation units 406. These electric charges result in noise. On the other hand, the stack-type solid-state imaging device 102 is configured to have a PN junction part which is shielded by the pixel electrode 46. Furthermore, in this embodiment, control is performed to apply, to the transparent electrode 47, a voltage having the second voltage value V2 at which carriers generated through photoelectric conversion cannot move. Since this application disables the carriers generated through the photoelectric conversion to move in the photoelectric conversion film 45, light is blocked more effectively. In this way, this embodiment makes it possible to reset the second electric charge accumulation units 406 of all the pixels to a reset level in a state where no unnecessary carriers are generated from incident light onto the second electric charge accumulation units 406 of all the pixels. Thus, it is possible to reduce occurrence of after images and unnecessary noise due to insufficient reset.

[Start of Exposure]

Next, the control unit 103 performs exposure start control for starting exposure by switching a voltage having the second voltage value V2 to a voltage having the first voltage value V1 to be applied to the transparent electrode 47.

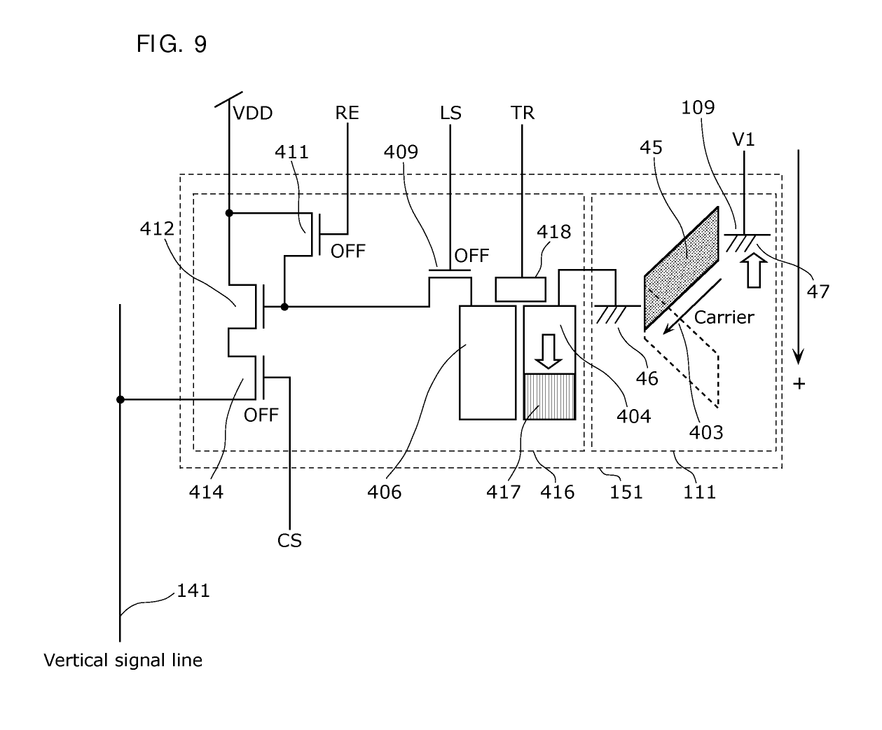

More specifically, simultaneously with the all reset, the signal processor 104 outputs a control signal 106 to the voltage control unit 105 so that a voltage 109 to be applied to the photoelectric conversion film 45 has the first voltage value V1 at which carriers generated through the photoelectric conversion can move. In response to this, as shown in FIG. 9, the voltage control unit 105 switches to a voltage 109 having the first voltage value V1 at which the carriers generated through the photoelectric conversion can move, as a voltage to be applied to the transparent electrode 47. In this way, exposure is started (S305). In addition, the carriers 403 generated through the photoelectric conversion in this state are accumulated as electric charges 417 in the first electric charge accumulation unit 404.

[End of Exposure]

After a predetermined time from the exposure start control (S305), the control unit 103 performs exposure end control for ending the exposure by switching the voltage having the first voltage value V1 to a voltage having the second voltage value V2 to be applied to the transparent electrode 47.

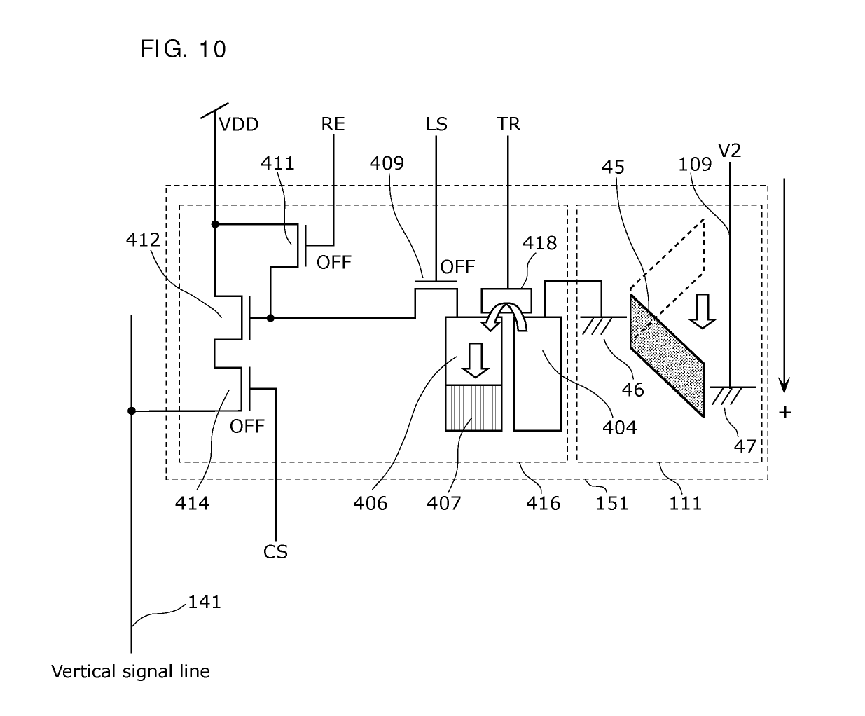

More specifically, the signal processor 104 outputs a control signal 106 to the voltage control unit 105 so that the voltage 109 to be applied to the transparent electrode 47 has the second voltage value V2 at which the carriers generated through the photoelectric conversion cannot move. In response to this, as shown in FIG. 10, the voltage control unit 105 switches to a voltage 109 having the second voltage value V2 at which the carriers generated through the photoelectric conversion cannot move, as a voltage to be applied to the transparent electrode 47. In this way, the exposure is ended (S306).

Here, the exposure time is the time from when a switch is made to the voltage 109 having the first voltage value V1 at which the carriers generated through the photoelectric conversion can move (S305) to when a switch is made back to the voltage 109 having the second voltage value V2 (S306) at which the carriers generated through the photoelectric conversion cannot move. The pixel circuit unit 416 reads the signal charges photo-electrically converted by the photoelectric conversion film 45 in the exposure time, and accumulates the read signal charges.

In addition, the signal processor 104 outputs, to the voltage control unit 105, a control signal 106 for controlling exposure time to a preset time. Upon receiving the control signal 106, the voltage control unit 105 controls the voltage 109 to be applied to the transparent electrode 47 of the solid-state imaging device 102.

[Reading]

After the exposure control (S306) is performed, the control unit 103 performs read control for sequentially reading signal charges accumulated in the plurality of pixel circuit units 416 included in the plurality of pixels 151.

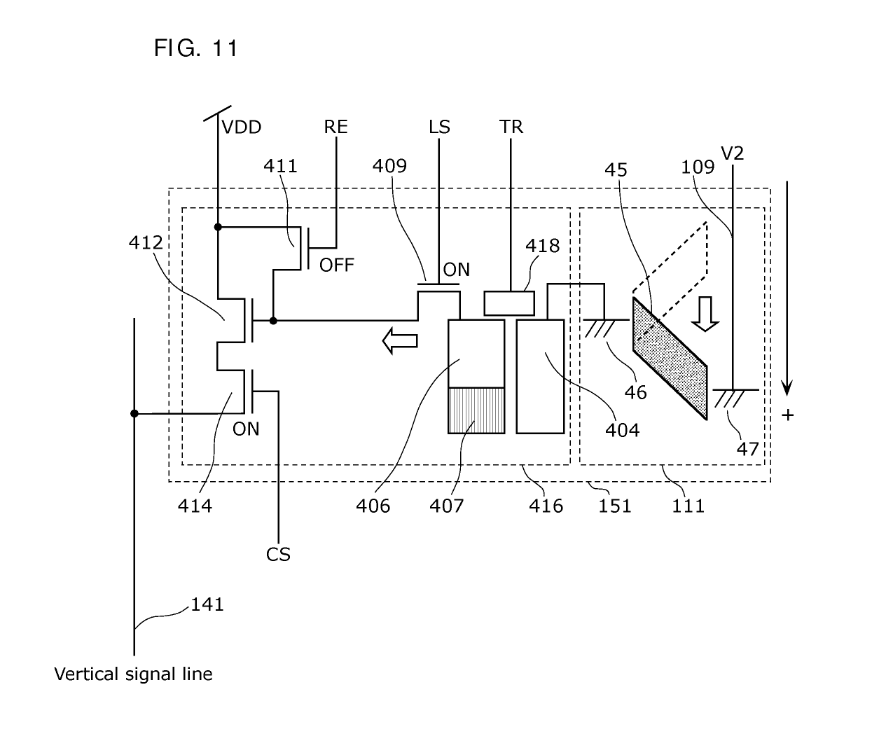

More specifically, as shown in FIG. 10, the control unit 103 applies a voltage having the second voltage value V2 to the transparent electrode 47 and simultaneously switching ON the transfer transistors 418 of all the pixels, and thereby transfers signal charges accumulated in the first electric charge accumulation units 404 to the second electric charge accumulation units 406. Next, as shown in FIG. 11, the signal processor 104 switches ON the line selection transistors 409 and the column selection transistors 414 so as to sequentially read, from the plurality of pixels 151, signals according to the electric charges 407 accumulated in their respective second electric charge accumulation units 406 (S307). In this way, no image distortion due to reading error occurs. In other words, the electric charges are accumulated simultaneously in all the pixels.

After the read control is performed (S307), the control unit 103 performs reset control again.

More specifically, the signal processor 104 outputs a control signal 106 to the voltage control unit 105 so that a voltage 109 to be applied to the photoelectric conversion film 45 has the first voltage value V1 at which carriers generated through the photoelectric conversion can move. Next, as shown in FIG. 8, the signal processor 104 activates reset signals RE and line selection signals LS for all the pixels 151. Thus, the reset transistors 411 and the line selection transistors 409 are switched ON. In this way, electric charges accumulated in the second electric charge accumulation units 406 of all the pixels 151 are reset (S308).

Next, as shown in FIG. 7, the voltage control unit 105 switches to a voltage 109 having the first voltage value V1 at which the carriers generated through the photoelectric conversion can move, as a voltage to be applied to the transparent electrode 47 (S309). Next, the imaging device 101 transits to the monitor mode (S301) again.

When still images are sequentially imaged, a mode transition is made to S303 after S309.

In this way, the imaging device 101 according to this embodiment makes it possible to capture still images without any mechanical shutter for exposure control, by controlling voltages to be applied to the photoelectric conversion film of the solid-state imaging device.

The aforementioned reset signals RE are, for example, tapered signals. In other words, the control unit 103 may switch ON the reset transistors 411 using the tapered signals in reset control so as to reset signal charges accumulated in the pixel circuit unit 416. Here, a tapered signal is a signal having a voltage level which changes gradually from a voltage level at which a reset transistor 411 is switched OFF to a voltage level at which the reset transistor 411 is switched ON, instead of having a voltage level which changes suddenly.

In this way, the control unit 103 can reduce random noise which is generated in the reset transistor 411 by means of the signal processor 104 controlling time constants of the tapered reset signals RE after creating a more effective light blocking state by switching to the voltage 109 having the second voltage value V2 at which carriers generated through photoelectric conversion cannot move, as the voltage to be applied to the transparent electrode 47.

The imaging device according to this embodiment has been described above. It is to be noted that the above exemplary embodiment should not be interpreted as limiting the present disclosure.

In addition, the processing units of the imaging device according to the embodiment are typically realized as LSIs which are integrated circuits. The structural units may be made as separate individual chips, or some or all of them may be made as a single chip.

In addition, the means for circuit integration is not limited to an LSI, and implementation with a dedicated circuit or a general-purpose processor is also available. It is also possible to use a Field Programmable Gate Array (FPGA) that is programmable after the LSI is manufactured, or a reconfigurable processor in which connections and settings of circuit cells within the LSI are reconfigurable.

In addition, some of the functions of the imaging device according to this embodiment of the present disclosure may be realized by a processor such as a CPU executing a computer program.

Although the structural elements have straight-line-shaped corner portions and sides in the cross-sectional views etc, structural elements manufactured to have round-shaped corner portions and sides are included in the scope of the present disclosure.

In addition, some of the functions of the imaging device according to this embodiment and variations of the embodiment may be arbitrarily combined.

In addition, all the numerals used in the above description are non-limiting exemplary ones for specifically explaining the present disclosure, and thus should not be interpreted as limiting the present disclosure. Furthermore, logical levels represented as High and Low and switching states represented by ON and OFF are non-limiting exemplary ones for specifically explaining the present disclosure. Thus, it is also possible to achieve an equivalent result by differently combining some of the exemplary logical levels and switching states.

In addition, the n-type and p-type of the transistors etc. are shown as exemplary ones for specifically explaining the present disclosure. Thus, it is also possible to achieve an equivalent result when the n-type and p-type are reversed. In addition, the connection relationships between the structural elements are non-limiting exemplary ones for specifically explaining the present disclosure, and thus should not be interpreted as limiting the present disclosure.

In addition, the functional blocks in the block diagrams are non-limiting exemplary ones. Thus, some of the functional blocks may be integrated into a single functional block, one of the functional blocks may be divided into plural blocks, and/or one or more of the functions of one of the functional blocks may be moved to another one of the functional blocks. In addition, similar functions of some of the functional blocks may be executed by a single hardware or software item in parallel or in time division.

Although the above description relates to an example using MOS transistors, the present disclosure includes an example using other kinds of transistors.

Furthermore, various kinds of other variations of the embodiment are conceivable by a person skilled in the art without deviating from the inventive concept of the present disclosure, and thus such variations etc. are also included in the scope of the present disclosure.

### INDUSTRIAL APPLICABILITY

The present disclosure is applicable to imaging devices such as digital still cameras.

1. An imaging device comprising
a stack-type solid-state imaging device including a plurality of pixels arranged in a matrix above a semiconductor substrate,
wherein each of the pixels includes:
a photoelectric conversion film which is formed above the semiconductor substrate and performs photoelectric conversion on light to convert the light into signal charges;
a pixel electrode formed on a first surface of the photoelectric conversion film, the first surface being at a side of the semiconductor substrate;
a transparent electrode formed on a second surface of the photoelectric conversion film, the second surface being opposite to the first surface; and
a pixel circuit unit configured to read the signal charges generated through the photoelectric conversion by the photoelectric conversion film via the pixel electrode, and accumulate the read signal charges,
the imaging device further comprising
a control unit configured to control exposure time by selectively applying, to the transparent electrode, a voltage having a first voltage value at which the signal charges generated through the photoelectric conversion by the photoelectric conversion film move to the pixel circuit unit and a voltage having a second voltage value at which the signal charges do not move to the pixel circuit unit.

2. The imaging device according to claim 1,
wherein the control unit is configured to perform:
exposure start control for starting exposure by switching from the voltage having the second voltage value to the voltage having the first voltage value to be applied to the transparent electrode; and
exposure end control for ending the exposure by switching from the voltage having the first voltage value to the voltage having the second voltage value to be applied to the transparent electrode, after the exposure start control, and
the pixel circuit unit is configured to read the signal charges generated through the photoelectric conversion by the photoelectric conversion film during an exposure period starting when the exposure start control is performed and ending when the exposure end control is performed, and accumulate the read signal charges.

3. The imaging device according to claim 2,
wherein the control unit is further configured to perform read control for sequentially reading signal charges accumulated in a plurality of the pixel circuit units included in the respective pixels, after the exposure end control.

4. The imaging device according to claim 3,
wherein the pixel circuit unit is connected to the pixel electrode, and includes:
a first electric charge accumulation unit configured to accumulate the signal charges;
a second electric charge accumulation unit; and
a transfer transistor formed between the first electric charge accumulation unit and the second electric charge accumulation unit, and
in the read control, the control unit is configured to:
apply the voltage having the second voltage value to the transparent electrode and switch ON the transfer transistor to transfer the signal charges accumulated in the first electric charge accumulation unit to the second electric charge accumulation unit; and
sequentially read, from the pixels, signals according to signal charges accumulated in a plurality of the second electric charge accumulation units.

5. The imaging device according to claim 2,
wherein the control unit is further configured to perform reset control for (i) applying the voltage having the second voltage value to the transparent electrode, before the exposure start control, and (ii) resetting signal charges accumulated in a plurality of the pixel circuit units, before the exposure start control.

6. The imaging device according to claim 5,
wherein the control unit is further configured to perform the reset control, after the read control.

7. The imaging device according to claim 5,
wherein the pixel circuit unit includes a reset transistor for resetting the signal charges accumulated in the pixel circuit unit, and
in the reset control, the control unit is configured to reset the signal charges accumulated in the pixel circuit unit by switching ON the reset transistor using a tapered signal.
